(19) United States
(12) Patent Application Publication
(10) Pub. No.: US 2022/0029044 A1
(43) Pub. Date: Jan. 27, 2022

(54) METHOD FOR PREPARING A SOLAR CELL AND A SOLAR CELL

(71) Applicant: City University of Hong Kong, Kowloon (HK)

(72) Inventors: Jian Lu, Kowloon (HK); Jinjin Zhao, Shijiazhuang (CN); Lulu Pan, New Territories (HK); Xiao Su, Shijiazhuang (CN); Weizhong Hao, Shijiazhuang (CN); Shenghui Yi, Nanshan District (CN)

(21) Appl. No.: 16/938,039

(22) Filed: Jul. 24, 2020

(51) Int. Cl. H01L 31/18; H01L 51/00; H01L 31/052; H01L 51/44; H01L 51/56

(52) U.S. Cl. CPC H01L 31/1864; H01L 51/0097; H01L 51/56; H01L 51/44; H01L 31/052

(57) ABSTRACT

A method for preparing a solar cell including the step of cooling a photoelectric conversion layer to a target temperature by a cooling source, thereby introducing internal stress into the cooled photoelectric conversion layer. A solar cell prepared by the method of the present invention is also disclosed.

### TECHNICAL FIELD

The present invention relates to a method for preparing a solar cell and a solar cell, specifically, although not exclusively, to a method for preparing a solar cell and a solar cell with an improved efficiency and a prolonged service life.

### BACKGROUND

Solar energy is clean and not subject to geographical restrictions. At present, solar energy is the largest energy source that exists in the world and it is sustainable and totally inexhaustible. The annual solar energy reaching the earth's surface is equivalent to energy generated by 130 trillion tons of coal.

According to some market researches, the global solar cell market is expected to grow and continue to dominate. Countries with frequent power cuts and grid problems because of unstable power supplies have also been overcome by adopting solar cell systems. Therefore, the solar cell market has a huge space for development.

### BRIEF DESCRIPTION OF THE DRAWINGS

Embodiments of the present invention will now be described, by way of example, with reference to the accompanying drawings in which:

FIG. 1 is a block diagram showing the process flow of a method for preparing a solar cell in accordance with one embodiment of the present invention;

FIG. 2 XRD test analysis diagram of the crystal structure of the perovskite thin film provided by the present invention after different cooling treatment processes;

FIG. 3 is a schematic diagram of the light absorption performance of the perovskite solar cell provided by the present invention after different cooling treatment processes;

FIG. 4a shows a perovskite thin film of the present invention before subjecting to focused ion beam (FIB) cutting technique; and

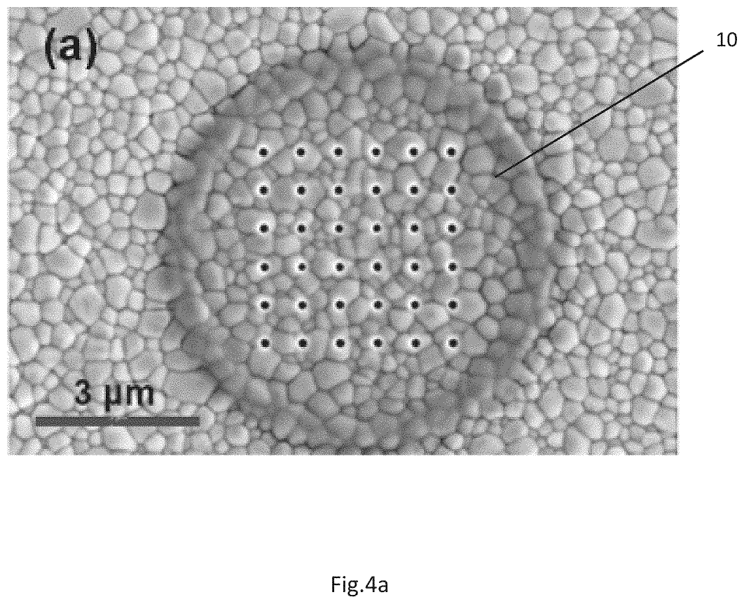

FIG. 4b shows a perovskite thin film of the present invention after subjecting to focused ion beam (FIB) cutting technique.

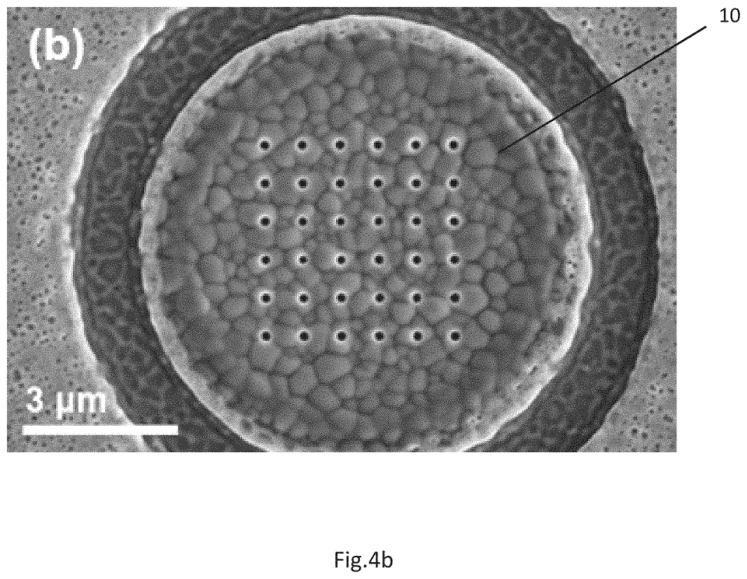

### SUMMARY OF THE INVENTION

In accordance with the first aspect of the present invention, there is provided a method for preparing a solar cell, comprising: step a) of cooling a photoelectric conversion layer to a target temperature by a cooling source, thereby introducing internal stress into the cooled photoelectric conversion layer.

In an embodiment of the first aspect, the photoelectric conversion layer is contactable by the cooling source.

In an embodiment of the first aspect, the method further includes step b), prior to step a), of annealing the photoelectric conversion layer at an annealing temperature.

In an embodiment of the first aspect, the target temperature is lower than the annealing temperature.

In an embodiment of the first aspect, the targeted temperature of the photoelectric conversion layer reaches the room temperature.

In an embodiment of the first aspect, the photoelectric conversion layer is cooled down for a predetermined period ranged from 1 min to 240 hours.

In an embodiment of the first aspect, the photoelectric conversion layer includes crystal lattice distortion.

In an embodiment of the first aspect, the photoelectric conversion layer is selected from p-n crystal silicon film, copper indium gallium selenide film, cadmium telluride film, gallium arsenide film, quantum dot film, organic photoelectric conversion layer and sensitized layer film.

In an embodiment of the first aspect, the photoelectric conversion layer is perovskite in the form of ABX₃.

In an embodiment of the first aspect, A is selected from methylamine ion CH₃NH₃⁺, formamidine ion CH(NH₂)₂⁺, 1-naphthyl ammonium ion NMA⁺, ethylamine ion CH₃CH₂NH₃⁺, propylamine ion CH₃CH₂CH₂NH₃⁺, butylamine ion CH₃CH₂CH₂CH₂NH₃⁺, ethylenediamine ion (CH₂NH₃)₂⁺, isobutylamine ion CH(CH₃)₂CH₂NH₃⁺, tert-butylamine ion C(CH₃)₃NH₃⁺, benzylamine ion C₆H₅CH₂NH₃⁺, cesium ion Cs⁺ and rubidium ion Rb⁺.

In an embodiment of the first aspect, B is selected from lead ion Pb²⁺, tin ion Sn²⁺, gallium ion Ga²⁺, germanium ion Ge²⁺, silver ion Ag⁺ and bismuth ions Bi³⁺.

In an embodiment of the first aspect, X is selected from chloride ions Cl⁻, bromide ions Br and iodide ions I⁻.

In an embodiment of the first aspect, the cooling source is in the form of at least one of gas, liquid and solid.

In an embodiment of the first aspect, the cooling source is selected from air, ice cubes, drikold, and liquid nitrogen.

In an embodiment of the first aspect, the annealing temperature is ranged from 1000° C. to −273° C.

In an embodiment of the first aspect, the method further includes step c), prior to step b), of forming the photoelectric conversion layer on a substrate.

In an embodiment of the first aspect, the photoelectric conversion layer is formed by a fabricating method selected from one of the following: a cutting method, a doctor blade method, a spray coating method, a chemical vapor deposition method, a slot coating method, a screen printing method, a sputtering method, a spray method Ink printing method, a pressure-assisted preparation method and a combination thereof.

In accordance with the second aspect of the invention, there is provided a solar cell prepared by the method of the present invention, wherein the solar cell is selected from crystal silicon solar cell, copper indium gallium selenide solar cell, cadmium telluride solar cell, gallium arsenide solar cell, quantum dot solar cell, organic solar cells, sensitized solar cells, and perovskite solar cells.

In an embodiment of the second aspect, the perovskite solar cell includes at least one of hard substrate or flexible substrate.

### DETAILED DESCRIPTION OF THE PREFERRED EMBODIMENT

Without wishing to be bound by theories, the inventors have, through their own research, trials, and experiments, devised that existing solar cells have a low durability to its residual stresses. Residual stresses in solar cells are caused by the external environment such as alternations of temperature difference, cosmic rays, wind and rain erosion, and so on, which seriously affect the photoelectric conversion performance and service life of solar cells.

For instance, the solar cell has to bear with alternations of temperature difference e.g. hot summer and severe cold winter, huge day-night temperature differences and space cosmic ray radiation damages. In these scenarios, stress concentration would be developed in the solar cells and hence accelerate degradation or failure of the solar cell. It would also bring about adverse effect to photoelectric conversion performance and service life of solar cells.

Residual stress may be caused by various factors. One of the main causations can be the difference in coefficient of thermal expansion between the photoelectric functional layer and the metal electrode. The residual stress may also be caused by different element doping gradient, polycrystalline particles and crystal equality in the solar cell, especially the new types of solar cell e.g. perovskite solar cells. As the performance of perovskite solar cells has been significantly improved by 25%, it would be worthwhile to explore and devise a new or otherwise improved solar conversion layer suitable for solar cell which may at least mitigate or alleviate the residual stress in the solar cell.

To tackle one or more of the above problems, the present invention provides a novel preparation method which overcomes the residual stressed disadvantage in the solar cell. By using a pre-stressed treatment, prestress is induced into solar cells for reducing the residual stress and improving the efficiency i.e. photoelectric conversion performance and service life. The preparation process of prestress is induced into the solar cell, which changes the key material structure of the crystal lattice distortion, improves the light absorption ability and photoelectric conversion performance, and reduces the influence of the stress generated on the performance and service life of the solar cell. A solar cell with a high efficiency and long service life is therefore obtained.

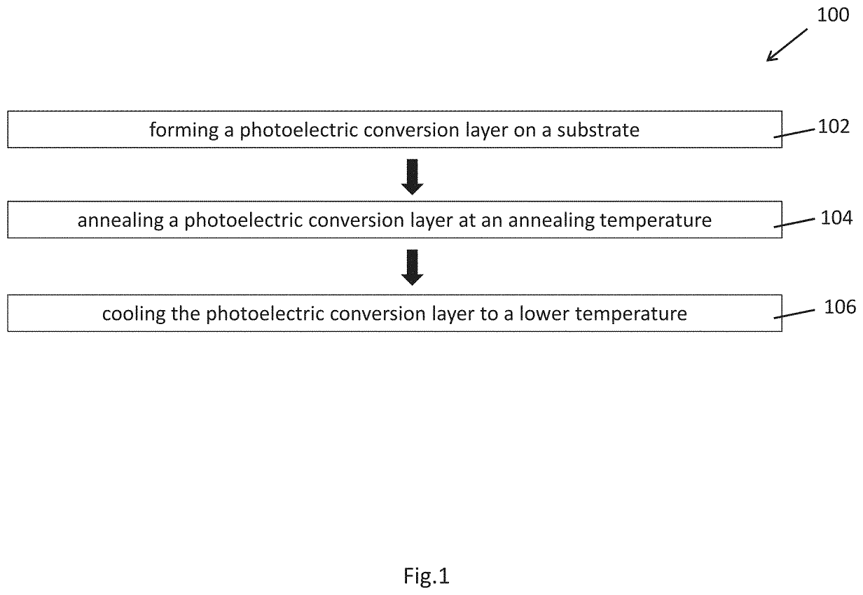

With reference to FIG. 1, there is provided a block diagram showing the process flow of a method 100 for preparing a solar cell, comprising the step of cooling a photoelectric conversion layer to a target temperature by a cooling source, thereby introducing internal stress into the cooled photoelectric conversion layer.

The solar cell is a solar panel which collects and converts sun energy into electricity. The solar cell primarily includes a photoelectric conversion layer which receives electromagnetic radiation e.g. light and in turn emits photoelectrons. The electricity is then collected by a battery module.

Turning now to the detailed workflow of the present invention, raw materials, such as perovskite, are subjected to one or more fabricating methods to form a thin film photoelectric conversion layer with crystal lattice distortion on a substrate as shown in step 102. For instance, the photoelectric conversion layer can be formed by the removal of a thin layer portion from a large area surface such as a cutting method, a doctor blade method. The photoelectric conversion layer can also be formed by other deposition techniques such as a spray coating method, a chemical vapor deposition method, a slot coating method, a screen printing method, a sputtering method, a spray method Ink printing method, a pressure-assisted preparation method etc. during which the raw material goes from one phase to another phase.

The thin film layer is then subjected to annealing treatment to improve photoelectric properties as shown in step 104. In this annealing treatment, crystallinity of the film is improved through promoting grain growth and recrystallization, which will significantly affect the electrical and optical properties of films. The annealing treatment may be conducted within an annealing temperature ranged from 1000° C. to −273° C. The film forms a photoelectric conversion layer.

After annealing the photoelectric conversion layer, physical cooling process is adopted to induce prestress field into solar cells as shown in step 106. The annealed photoelectric conversion layer at this point is still at a relatively high temperature. A cooling source with a lower temperature relative to the photoelectric conversion layer is used to cool down the temperature of the photoelectric conversion layer further to a target temperature below the annealing temperature.

In one example embodiment, the cooling method may be executed in that the cooling source at a lower temperature in contact with the solar cell after annealing at a higher temperature and finally take the temperature of the solar cell down to room temperature, so as to inducing the prestress field into the solar cell. As the photoelectric conversion layer is highly sensitive to temperature variations, the temperature of the photoelectric conversion layer, upon contacting the cooling source, would drop rapidly and in a linear manner.

Preferably, the prestressed treatment cooling method of the solar cell is from the highest temperature of 1000° C. to the lowest temperature of −273° C., and the cooling time is controlled from 1 minute to 240 hours.

The cooling source can be in any form i.e. gas, liquid and solid. For instance, the cooling source can be ice cubes, drikold (dry ice), or liquid nitrogen that is in direct contact with the photoelectric conversion layer. It may also be possible to transfer heat energy from the photoelectric conversion layer to the cooling source through another medium e.g. air. In this scenario, the low-temperature air surrounding the photoelectric conversion layer is the cooling source.

In one preferred example embodiment, the solar cell is a solar cell with high performance and which is sensitive to the cooling. Preferably, the solar cell is a novel perovskite solar cell that includes a multilayer structure. The multilayer structure includes a conductive substrate, a hole transport layer (HTL), a perovskite photoelectric conversion layer (light harvester), an electron transport layer (ETL) and a metal contact. The substrate is preferably a hard base or a flexible substrate. The ETL transfers photo-generated electrons from the perovskite layer to the counter electrode. The HTL is a layer which avoids the direct contact of the metal electrodes with the perovskite photoelectric conversion layer.

The perovskite has a general chemical formula of ABX₃ where A and B are cations of difference sizes and X is an anion that bonds to both cations. The size of the A atom is larger than that of the B atom.

Preferably, A is selected from methylamine ion CH₃NH₃⁺, formamidine ion CH(NH₂)₂⁺, 1-naphthyl ammonium ion NMA⁺, ethylamine ion CH₃CH₂NH₃⁺, propylamine ion CH₃CH₂CH₂NH₃⁺, butylamine ion CH₃CH₂CH₂CH₂NH₃⁺, ethylenediamine amine ion (CH₂NH₃)₂⁺, isobutylamine ion CH(CH₃)₂CH₂NH₃⁺, tert-butylamine ion C(CH₃)₃NH₃⁺, benzylamine ion C₆H₅CH₂NH₃⁺, cesium ion Cs⁺ and rubidium ion Rb⁺. B is selected from lead ion Pb²⁺, tin ion Sn²⁺, gallium ion Ga²⁺, germanium ion Ge²⁺, silver ion Ag⁺ and bismuth ions Bi³⁺. X is selected from chloride ions Cl⁻, bromide ions Br and iodide ions I⁻.

The perovskite photoelectric conversion layer is annealed and cooled at a temperature from a maximum of 200° C. to a minimum of −273° C. The cooling time is controlled from 1 minute to 240 hours.

Two exemplary embodiments of one aspect of the present invention are now described in detail below and the technical effect brought by the cooling process in the present invention will become apparent to a person skilled in the art.

In a first example embodiment of the present invention, a fluorine-doped tin oxide (FTO) conductive glass is provided as a substrate. A layer of nickel oxide (NiOx) film is then spray coated onto the conductive glass and annealed at 550° C. for 20 min to form a hole transport layer. Next, a photoelectric conversion layer is fabricated on the hole transport layer. In this arrangement, methylamine lead odide CH₃NH₃PbI₃ is spray coated onto the hole transport layer twice. In the first cycle, CH₃NH₃PbI₃ is spun at a rotation speed of 1000 r/min for 10 s. In the second cycle, CH₃NH₃PbI₃ is further spun at a rotation speed of 5000 r/min for 30 s. CH₃NH₃PbI₃ is rinsed with anisole (methoxybenzene) throughout the rotation.

Once the spin coating is completed, the CH₃NH₃PbI₃ is annealed at 110° C. for 10 min and then subjected to free cooling. Next, a layer of (6,6)-Phenyl C61 butyric acid methyl ester, namely [60] PCBM, is spin coated onto the photoelectric conversion layer at a rotation speed of 4000 r/min for 30 s to form an electron transport layer. A layer of 2,9-dimethyl-4,7-diphenyl-1,10-phenanthrolien, namely Bathocuproine (BCP) is spin coated onto the electron transport layer at a rotation speed 5000 r/min for 30 s to form a transition layer. Finally, conductive electrode, preferably silver Ag electrode is vapor-deposited onto the top and bottom surfaces to complete the fabrication of the battery cell.

In a second example embodiment of the present invention, the fabrication steps for forming the battery cell are almost identical to the first example embodiment, except the annealed methylamine lead odide CH₃NH₃PbI₃ film is rapidly cooled by dryice instead of free cooling.

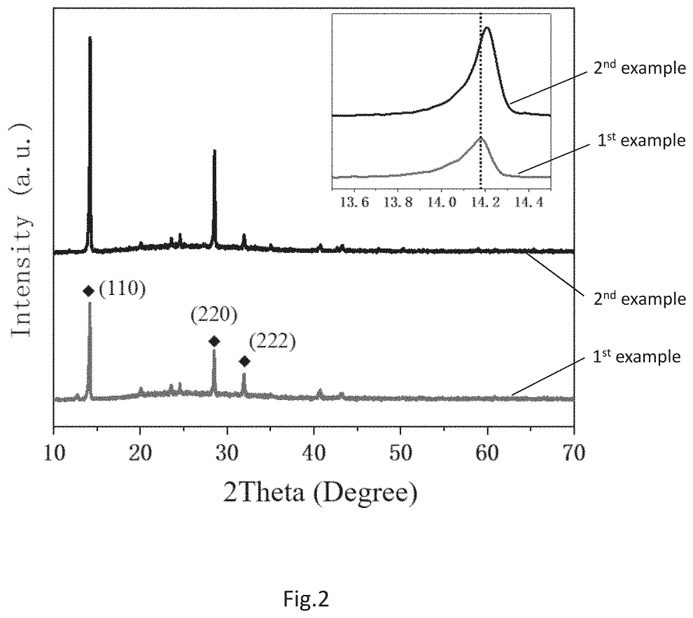

Referring to FIG. 2 for the X-ray diffraction (XRD) spectral analysis of the crystalline structure for the two samples. The x-axis corresponds to the angular position of the detector that rotates around the sample. In the plot, the Miller indices represent the peak intensity which are contributed by the x-ray diffraction from the {110}, {220} and {222} planes. The peak intensity of Example 2 at each of these planes is higher than that of Example 1. As the lattice spacing is inversely proportional to the Miller indices, the lattice spacing of the perovskite thin film of Example 2 is smaller than that of Example 1. The pre-stress generated in Example 2 is also greater than that of Example 1. These indicate that the lattice spacing has been reduced by introduction of prestress during the cooling process.

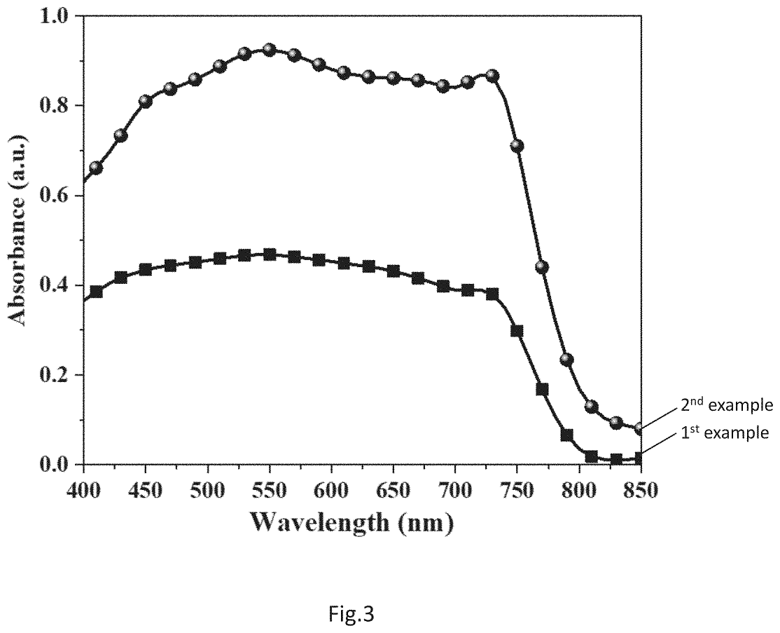

The performance of the UV light absorption of Example 1 and Example 2 are also compared in FIG. 3. Advantageously, the general absorbance of Example 2 is higher than that of Example 1 in the wavelength ranged from 400 to 850 nm. In particular, the absorbance of Example 2 is 50% higher than that of Example 1 at around 400 nm which is the wavelength of near ultraviolet (NUV) light. All these parameters indicate that the additional cooling process subsequent to the annealing process has drastically improved the absorbance of the solar cell.

The prestress release of a perovskite thin film 10 of the present invention is also studied. The perovskite thin film 10 fabricated by Example 2 is subjected to focused ion beam (FIB) cutting. The rapid cooling process in Example 2 generates a prestress of 2×10⁻³.

Apart from the manufacturing of novel typed perovskite solar cell, the present invention is also applicable for other traditional and industrial solar cells such as crystal silicon (c-Si) solar cells, copper indium gallium selenide (CIGS) solar cells, cadmium telluride (CdTe) solar cells, gallium arsenide (GaAs) solar cell, quantum dot solar cells (QDSC), organic solar cells (OSC), and sensitized solar cells. In each of these types of solar cells, the intermediate energy conversion layer is annealed at different annealing temperatures and subsequently subjected to cooling process.

In one example embodiment, the solar cell is a crystal silicon (c-Si) solar cell. The silicon is arranged in crystalline forms, either polycrystalline silicon (poly-Si) consisting of small crystals or monocrystalline silicon (mono-Si) with a continuous crystal. The p-n crystal silicon film is annealed and cooled at a temperature from a maximum of 1000° C. to a minimum of −273° C. The cooling time is controlled from 1 minute to 240 hours.

In one further example embodiment, the solar cell is a copper indium gallium selenide (CIGS) solar cell. A thin layer of copper, indium, gallium and selenium is deposited on a glass or plastic backing, along with electrodes on the front and back to collect current. During the formation of the layer, the copper indium gallium selenide film is annealed and cooled at a temperature from a maximum of 800° C. to a minimum of −273° C. The cooling time is controlled from 1 minute to 240 hours.

In one further example embodiment, the solar cell is a cadmium telluride (CdTe) solar cell. A cadmium telluride is formed in a thin semiconductor layer to absorb and convert sunlight to electricity. During the formation of the layer, the cadmium telluride film is annealed and cooled at a temperature from a maximum of 800° C. to a minimum of −273° C. The cooling time is controlled from 1 minute to 240 hours.

In one further example embodiment, the solar cell is gallium arsenide (GaAs) solar cell. The gallium arsenide film is annealed and cooled at a temperature from a maximum of 800° C. to a minimum of −273° C. The cooling time is controlled from 1 minute to 240 hours.

In one further example embodiment, the solar cell is a quantum dot solar cell (QDSC) which uses quantum dots as an absorbing photovoltaic material. The quantum dot film is annealed and cooled at a temperature from a maximum of 600° C. to a minimum of −273° C. The cooling time is controlled from 1 minute to 240 hours.

In one further example embodiment, the solar cell is an organic solar cell (OSC) or a plastic solar cell which uses organic electronics such as conductive organic polymers or small organic molecules for light absorption and charge transport to produce electricity from sunlight by the photovoltaic effect. The organic photoelectric conversion layer is annealed and cooled at a temperature from a maximum of 200° C. to a minimum of −273° C. The cooling time is controlled from 1 minute to 240 hours.

In one yet further example embodiment, the solar cell is a sensitized solar cell.

The sensitized layer film is annealed and cooled at a temperature from a maximum of 600° C. to a minimum of −273° C. The cooling time is controlled from 1 minute to 240 hours.

In contrast to solar-cell based on traditional technology, the residual stressed energy generated in the fabrication processes consumed during the prestressed treatment of the present invention. This reduces the influence of the prestress on the solar-cell performance. Thus, the prestressed solar cells in the present invention have higher efficiencies and provide longer service life abilities. The cooling treatment based on solar cell is controllable. In addition, the present method requires low equipment and material costs, low power consumption and simple setup.

Embodiments of the present invention can also be applied to various applications and fields, for example space solar cell or flexible thin film solar cells.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

Any reference to prior art contained herein is not to be taken as an admission that the information is common general knowledge, unless otherwise indicated.

1. A method for preparing a solar cell, comprising: step a) of cooling a photoelectric conversion layer to a target temperature by a cooling source, thereby introducing internal stress into the cooled photoelectric conversion layer.

2. A method for preparing a solar cell in accordance with claim 1, wherein the photoelectric conversion layer is contactable by the cooling source.

3. A method for preparing a solar cell in accordance with claim 1, further including step b), prior to step a), of annealing the photoelectric conversion layer at an annealing temperature.

4. A method for preparing a solar cell in accordance with claim 3, wherein the target temperature is lower than the annealing temperature.

5. A method for preparing a solar cell in accordance with claim 1, wherein the targeted temperature of the photoelectric conversion layer reaches the room temperature.

6. A method for preparing a solar cell in accordance with claim 1, wherein the photoelectric conversion layer is cooled down for a predetermined period ranged from 1 min to 240 hours.

7. A method for preparing a solar cell in accordance with claim 1, wherein the photoelectric conversion layer includes crystal lattice distortion.

8. A method for preparing a solar cell in accordance with claim 1, wherein the photoelectric conversion layer is selected from p-n crystal silicon film, copper indium gallium selenide film, cadmium telluride film, gallium arsenide film, quantum dot film, organic photoelectric conversion layer and sensitized layer film.

9. A method for preparing a solar cell in accordance with claim 1, wherein the photoelectric conversion layer is perovskite in the form of ABX₃.

10. A method for preparing a solar cell in accordance with claim 9, wherein A is selected from methylamine ion CH₃NH₃⁺, formamidine ion CH(NH₂)₂⁺, 1-naphthyl ammonium ion NMA+, ethylamine ion CH₃CH₂NH₃⁺, propylamine ion CH₃CH₂CH₂NH₃⁺, butylamine ion CH₃CH₂CH₂CH₂NH₃⁺, ethylenediamine ion (CH₂NH₃)₂⁺, isobutylamine ion CH(CH₃)₂CH₂NH₃⁺, tert-butylamine ion C(CH₃)₃NH₃⁺, benzylamine ion C₆H₅CH₂NH₃⁺, cesium ion Cs⁺ and rubidium ion Rb⁺.

11. A method for preparing a solar cell in accordance with claim 9, wherein B is selected from lead ion Pb²⁺, tin ion Sn²⁺, gallium ion Ga²⁺, germanium ion Ge²⁺, silver ion Ag⁺ and bismuth ions Bi³⁺.

12. A method for preparing a solar cell in accordance with claim 9, wherein X is selected from chloride ions Cl⁻, bromide ions Br and iodide ions I⁻.

13. A method for preparing a solar cell in accordance with claim 1, wherein the cooling source is in the form of at least one of gas, liquid and solid.

14. A method for preparing a solar cell in accordance with claim 13, wherein the cooling source is selected from air, ice cubes, drikold, and liquid nitrogen.

15. A method for preparing a solar cell in accordance with claim 3, wherein the annealing temperature is ranged from 1000° C. to −273° C.

16. A method for preparing a solar cell in accordance with claim 3, further including step c), prior to step b), of forming the photoelectric conversion layer on a substrate.

17. A method for preparing a solar cell in accordance with claim 16, wherein the photoelectric conversion layer is formed by a fabricating method selected from one of the following: a cutting method, a doctor blade method, a spray coating method, a chemical vapor deposition method, a slot coating method, a screen printing method, a sputtering method, a spray method Ink printing method, a pressure-assisted preparation method and a combination thereof.

18. A solar cell prepared by the method in accordance with claim 1, wherein the solar cell is selected from crystal silicon solar cell, copper indium gallium selenide solar cell, cadmium telluride solar cell, gallium arsenide solar cell, quantum dot solar cell, organic solar cells, sensitized solar cells, and perovskite solar cells.

19. A solar cell in accordance with claim 18, wherein the perovskite solar cell includes at least one of hard substrate or flexible substrate.
